(19) United States
(12) Patent Application Publication
(10) Pub. No.: US 2026/0144097 A1
(43) Pub. Date: May 21, 2026

(54) SEMICONDUCTOR STRUCTURES AND METHODS OF FORMING THE SAME

(71) Applicant: Taiwan Semiconductor Manufacturing Company, Ltd., Hsinchu (TW)

(72) Inventors: Chen-Shien CHEN, Hsinchu County (TW); Yinlung Lu, Hsinchu (TW); Yao-Chun Chuang, Hsinchu City (TW); Tien-Chung Yang, Hsinchu City (TW); Wei-Hao Chen, New Taipei City (TW); Hsu-Hsien Chen, Hsinchu City (TW); SyuFong Li, Taoyuan (TW); Jyun-Lin Wu, Hsinchu City (TW)

(73) Assignee: Taiwan Semiconductor Manufacturing Company, Ltd., Hsinchu (TW)

(21) Appl. No.: 18/951,651

(22) Filed: Nov. 19, 2024

(51) Int. Cl. H01L 23/498; H01L 21/768; H01L 23/00

(52) U.S. Cl. CPC H10W 70/635; H10W 20/056; H10W 20/089; H10W 70/65; H10W 90/701; H10W 90/794

(57) ABSTRACT

A method of forming a semiconductor structure is provided. A substrate is provided with a first region and a second region. A through via is formed in the substrate in the first region. A first conductive pattern is formed covering the through via in the first region and a first conductive layer is simultaneously formed on the substrate in the second region. A second conductive pattern is formed on the first conductive pattern in the first region and a second conductive layer is simultaneously formed on the first conductive layer in the second region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Although the existing semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 16 illustrate cross-sectional views of a method of forming a semiconductor structure in accordance with some embodiments of the present disclosure.

FIG. 17A illustrates top and cross-sectional views of part of the semiconductor structure in FIG. 16 in accordance with some embodiments of the present disclosure.

FIG. 17B to FIG. 17D illustrate different cross-sectional views of part of the semiconductor structure in FIG. 16 in accordance with other embodiments of the present disclosure.

FIG. 18 to FIG. 20 illustrate different cross-sectional views of semiconductor structures in accordance with some embodiments of the present disclosure.

FIG. 21 illustrates a flowchart of a method of forming a semiconductor structure according to some embodiments of the present disclosure.

FIG. 22 illustrates a flowchart of a method of forming a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

The present disclosure is directed to semiconductor structures and forming methods thereof. In some embodiments, one or more through substrate vias are formed through a semiconductor substrate of the die or wafer. The through substrate vias can be used to electrically connect components at opposite sides of the semiconductor substrate and allow for stacking of multiple dies to form 3D packages or 3D integrated circuits (3DICs). The related through substrate via is formed by defining a single deep opening with a dry etching and a wet strip, followed by a single electroplating process. The related guard ring is required for the related through substrate via to protect against the moisture effect caused by the long-time wet strip process during the deep opening defining step. However, the through substrate via of the disclosure is defined by forming multiple shallow openings and performing multiple electroplating processes alternately. The wet strip process is short and the moisture effect is relatively minor, and thus, the related guard ring is not necessary. Besides, in the disclosure, the shallow conductive patterns of the through substrate via and the adjacent conductive layers of the interconnect structure can be defined simultaneously with the same photomasks. The method of the disclosure is compatible with the existing processes without increasing process steps and costs.

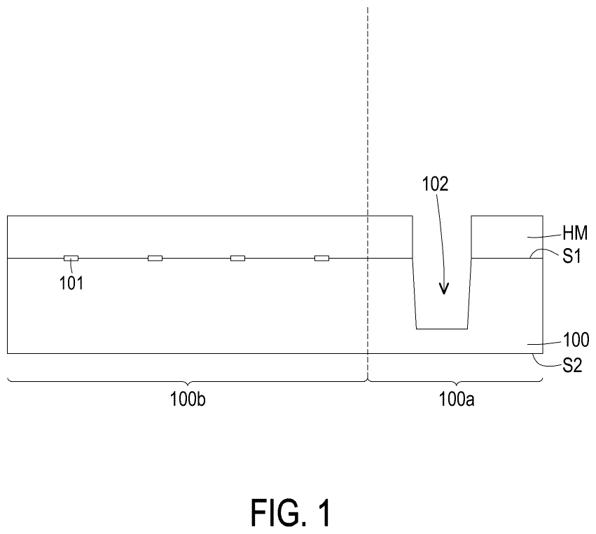

FIG. 1 to FIG. 16 illustrate cross-sectional views of a method of forming a semiconductor structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 1 to FIG. 16 are described in relation to a method, it is appreciated that the structures disclosed in FIG. 1 to FIG. 16 are not limited to such a method, but instead may stand alone as structures independent of the method.

Referring to FIG. 1, a substrate 100 is provided. In some embodiments, the substrate 100 may be a semiconductor substrate such as a silicon substrate. In other embodiments, the substrate 100 includes an elementary semiconductor such as germanium; a compound semiconductor including silicon carbon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates such as multi-layered or gradient substrates may also be used. The substrate 100 is hundreds of micron-scale. The substrate 100 has a first region 100a and a second region 100b adjacent to each other. In some embodiments, the first region 100a is a through via region, and the second region 100b is a device region. The substrate has a first side S1 and a second side S2 opposite to the first side S1. In some embodiments, the first side S1 is a front side or an active side, and the second side S2 is a back side or an inactive side.

In some embodiments, devices 101 are formed at the first side S1 of the substrate 100. In some embodiments, the devices 101 may include active and/or passive devices. For example, the devices 101 may include transistors, diodes, capacitors, resistors, or the like, formed by any suitable formation method.

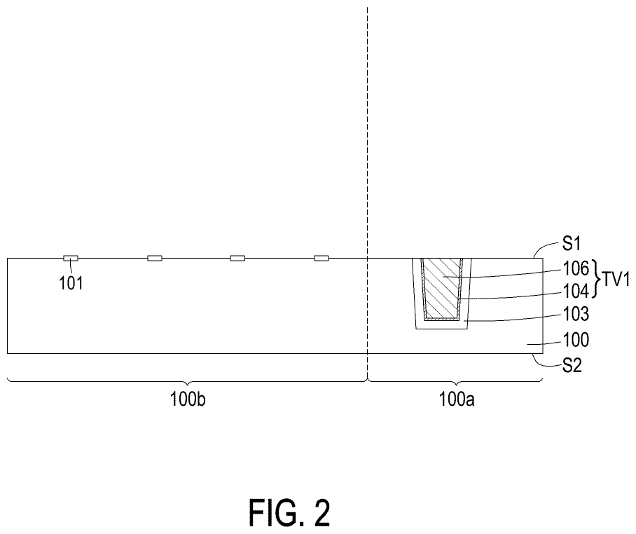

FIG. 1 and FIG. 2 illustrate forming at least one through via TV1 in the substrate 100. In some embodiments, at least one opening 102 is formed extending from the first side S1 to the second side S2 of the substrate 100 by photolithography and etching processes. In some embodiments, a mask layer HM (e.g., a photoresist material, a dielectric material or both) is formed over the substrate 100, and an etching process is performed to the substrate by using the mask layer HM as an etching mask, so as to form the opening 102 in the substrate 100. The opening 102 may be defined by one photomask. The mask layer HM is then removed by a suitable etching process.

Thereafter, the opening 102 is lined with an insulating liner layer 103. The insulating liner layer 103 may include silicon oxide and may be formed by a depositing process such as a chemical vapor deposition (CVD) process. Afterwards, a metal liner layer 104 and a metal layer 106 are formed in the opening 102. In some embodiments, the metal liner layer 104 includes a barrier layer and a seed layer. The barrier layer may include Ta, TaN, Ti, TiN, CoW or a combination thereof. The seed layer may include Cu, Al or the like. For example, the metal liner layer 104 includes Ti and Cu. The metal liner layer 104 may be formed by a sputtering process or a deposition process. The metal layer 106 may include Cu, Al, Ti, Ta, W, Ru, Co, Ni, the like, or a combination thereof. The metal layer 106 may be formed by an electroplating process or deposition process. In some embodiments, the metal layer 106 is formed in the opening 102 by using the metal liner layer 104 as a seed. Excess materials outside of the opening 102 are then removed by a planarization process, such as a chemical mechanical polishing (CMP) process. The remaining metal liner layer 104 and the remaining metal layer 106 constitute a lower through via TV1 in the first region 100a in some examples. The top surface of the lower through via TV1 is substantially flush with the first side S1 of the substrate 100. The lower through via TV1 is referred to as a “zeroth conductive pattern” of a through substrate via in some examples.

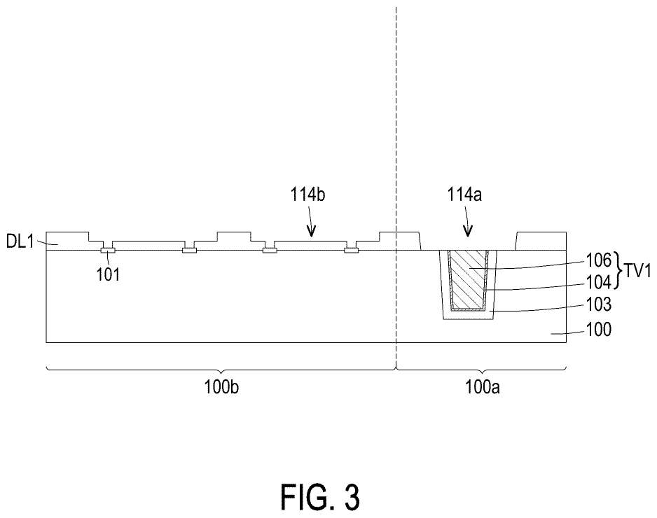

FIG. 3 to FIG. 9 illustrate forming an upper through via TV2 in the first region 100a and an interconnection structure IS1 in the second region 100b simultaneously. In some embodiments, the upper through via TV2 includes multiple stacked conductive patterns, the interconnection structure IS1 includes multiple stacked conductive layers, and the conductive pattern and the conductive layer at substantially the same level are formed simultaneously. The detailed process is described below.

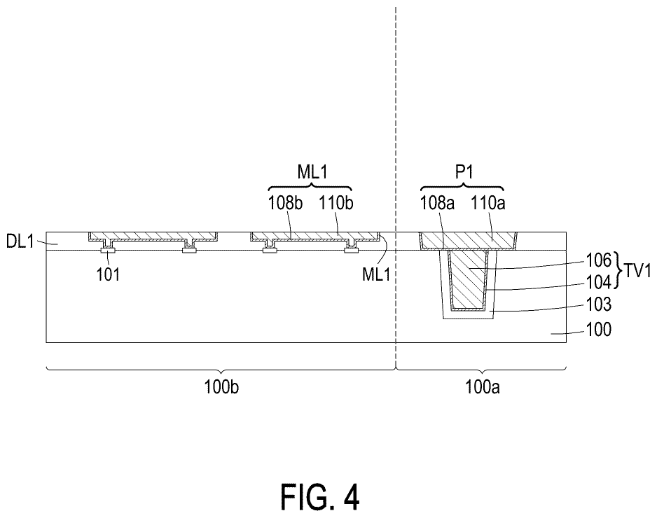

FIG. 3 and FIG. 4 illustrate forming a first conductive pattern P1 on the lower through via TV1 in the first region 100a and simultaneously forming a first conductive layer ML1 on the substrate 100 in the second region 100b.

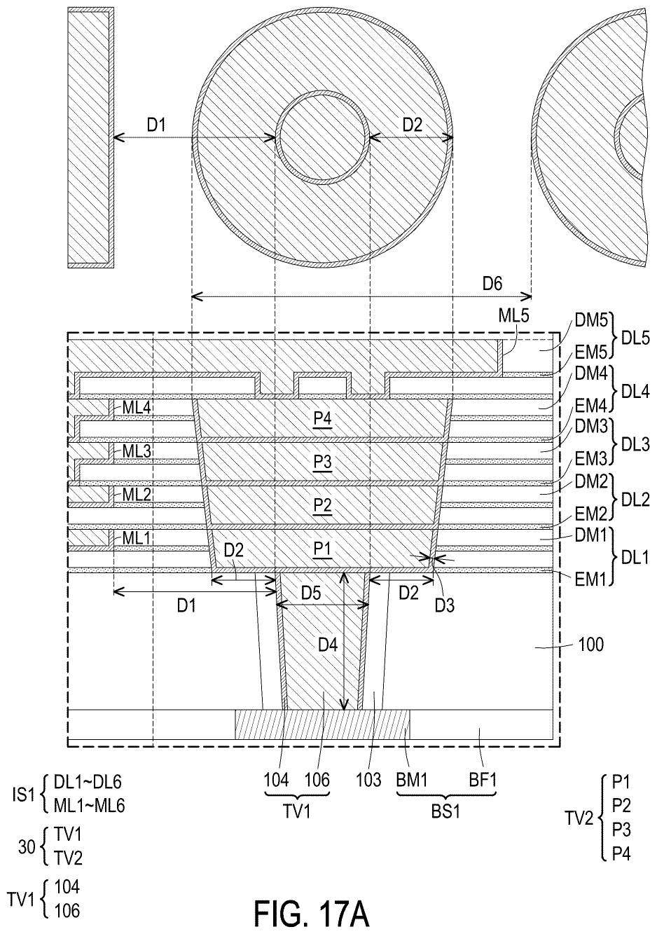

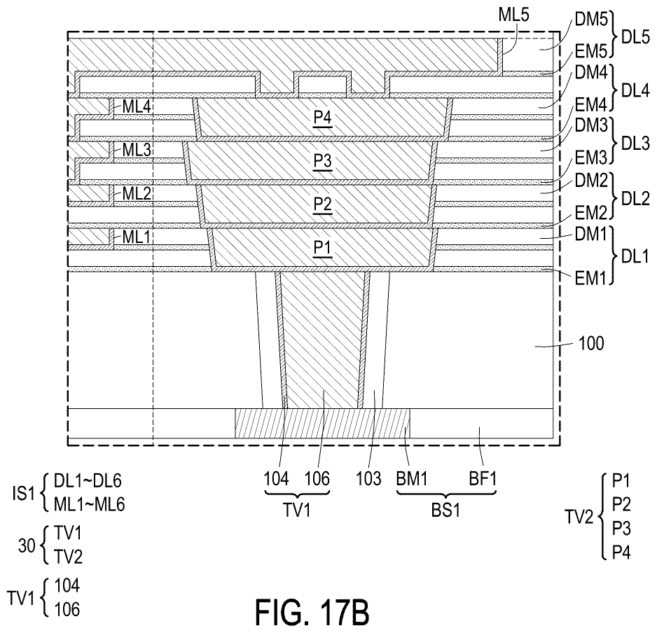

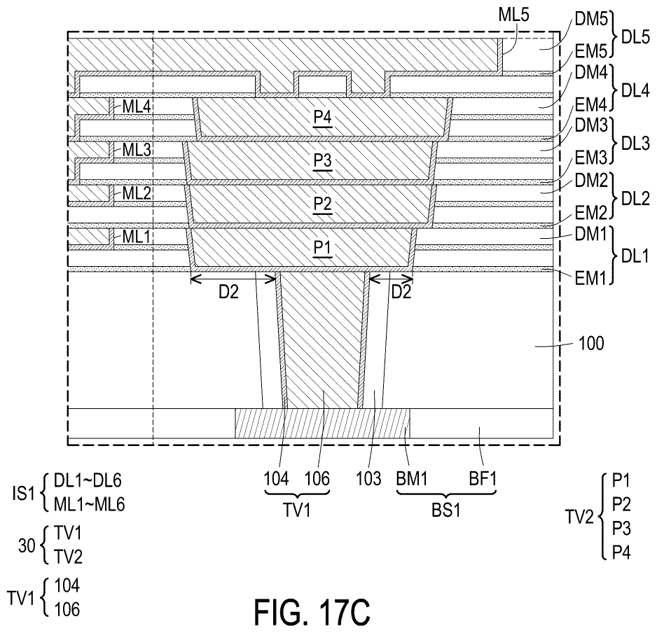

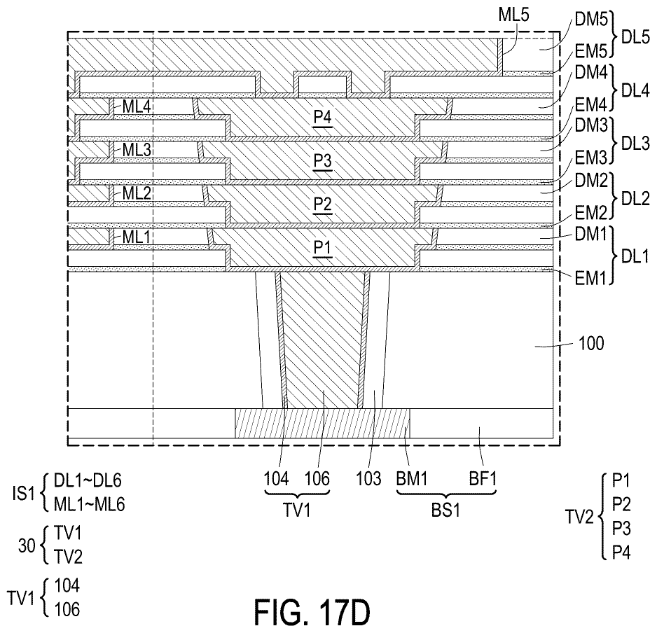

In some embodiments, a dielectric layer DL1 is formed on the substrate 100 across the first region 100a and the second region 100b. The dielectric layer DL1 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, as shown in the enlarged views of FIG. 17A to FIG. 17D, the dielectric layer DL1 may include two dielectric materials DM1 and two etching stop materials EM1 alternatively stacked. The dielectric layer DL1 is patterned to form a first-level opening 114a in the first region 100a and first-level openings 114b in the second region 100b. The first-level openings 114a and 114b are formed simultaneously by the same photolithography and etching processes. The first-level opening 114a in the first region 100a is a hole for defining a part of an upper through via. The first-level opening 114b in the second region 100b is a dual damascene opening including a trench for defining a line and an underlying hole for defining a via. The first-level openings 114a and 114b are defined by the same photomask(s). Depending on the process, one or two photomasks may be applied to form the first-level openings 114a and 114b.

Referring to FIG. 4, a metal liner layer 108a and a metal layer 110a are formed in the first-level opening 114a in the first region 100a, and a metal liner layer 108b and a metal layer 110b are formed in the first-level opening 114b in the second region 100b.

In some embodiments, each of the metal liner layers 108a and 108b includes a barrier layer and a seed layer. The barrier layer may include Ta, TaN, Ti, TiN, CoW or a combination thereof. The seed layer may include Cu, Al or the like. For example, each of the metal liner layers 108a and 108b includes Ti and Cu. The metal liner layers 108a and 108b are formed simultaneously by the same sputtering process or deposition process.

In some embodiments, each of the metal layers 110a and 110b may include Cu, Al, Ti, Ta, W, Ru, Co, Ni, the like, or a combination thereof. The metal layers 110a and 110b are formed simultaneously by the same electroplating process or deposition process. For example, the metal layer 110a and 110b are then formed in the first-level openings 114a and 114b by using the metal liner layers 108a and 108b as seeds, respectively.

Thereafter, excess materials outside of the first-level openings 114a and 114b are removed by a planarization process, such as a chemical mechanical polishing (CMP) process. The remaining metal liner layer 108a and the remaining metal layer 110a constitute a first conductive pattern P1 covering the lower through via TV1 in the first region 100a in some examples. The remaining metal liner layer 108b and the remaining metal layer 110b constitute a first metal layer ML1 on the devices 101 in the second region 100b in some examples. The top surface of the first conductive pattern P1 is substantially flush with the top surface of the first metal layer ML1.

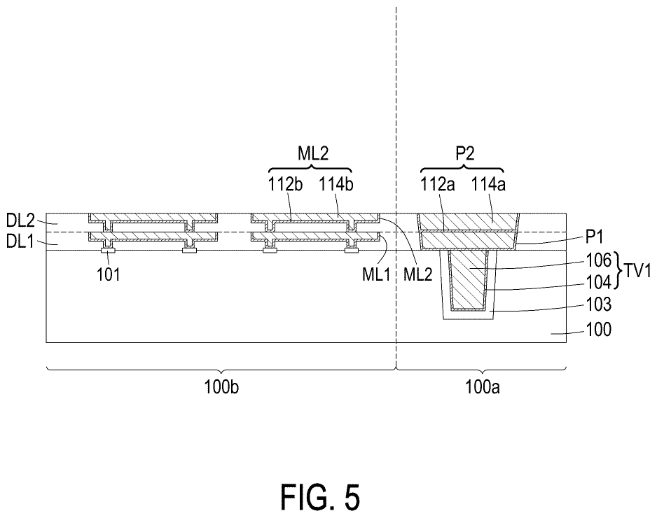

FIG. 5 illustrates forming a second conductive pattern P2 on the first conductive pattern P1 in the first region 100a and simultaneously forming a second conductive layer ML2 on the first conductive layer ML1 in the second region 100b. In some embodiments, the method of forming the second conductive pattern P2 and the second conductive layer ML2 is similar to the method of forming the first conductive pattern P1 and the first conductive layer ML1.

In some embodiments, a dielectric layer DL2 is formed on the dielectric layer DL1 across the first region 100a and the second region 100b. The dielectric layer DL2 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, as shown in the enlarged views of FIG. 17A to FIG. 17D, the dielectric layer DL2 may include two dielectric materials DM2 and two etching stop materials EM2 alternatively stacked. The dielectric layer DL2 is patterned to form a second-level opening in the first region 100a and second-level openings in the second region 100b. The second-level openings are formed simultaneously by the same photolithography and etching processes. The second-level opening in the first region 100a is a hole for defining a part of an upper through via. The second-level opening in the second region 100b is a dual damascene opening including a trench for defining a line and an underlying hole for defining a via. The second-level openings are defined by the same photomask(s). Depending on the process, one or two photomasks may be applied to form the second-level openings.

Thereafter, a metal liner layer 112a and a metal layer 114a are formed in the second-level opening in the first region 100a, and a metal liner layer 112b and a metal layer 114b are formed in the second-level openings in the second region 100b.

In some embodiments, each of the metal liner layers 112a and 112b includes a barrier layer and a seed layer. The barrier layer may include Ta, TaN, Ti, TiN, CoW or a combination thereof. The seed layer may include Cu, Al or the like. For example, each of the metal liner layers 112a and 112b includes Ti and Cu. The metal liner layers 112a and 112b are formed simultaneously by the same sputtering process or deposition process.

In some embodiments, each of the metal layers 114a and 114b may include Cu, Al, Ti, Ta, W, Ru, Co, Ni, the like, or a combination thereof. The metal layers 114a and 114b are formed simultaneously by the same electroplating process or deposition process. For example, the metal layer 114a and 114b are then formed in the second-level openings by using the metal liner layers 112a and 112b as seeds, respectively.

Thereafter, excess materials outside of the second-level openings are removed by a planarization process, such as a chemical mechanical polishing (CMP) process. The remaining metal liner layer 112a and the remaining metal layer 114a constitute a second conductive pattern P2 on the first conductive pattern P1 in the first region 100a in some examples. The remaining metal liner layer 112b and the remaining metal layer 114b constitute a second metal layer ML2 on the first metal layer ML1 in the second region 100b in some examples.

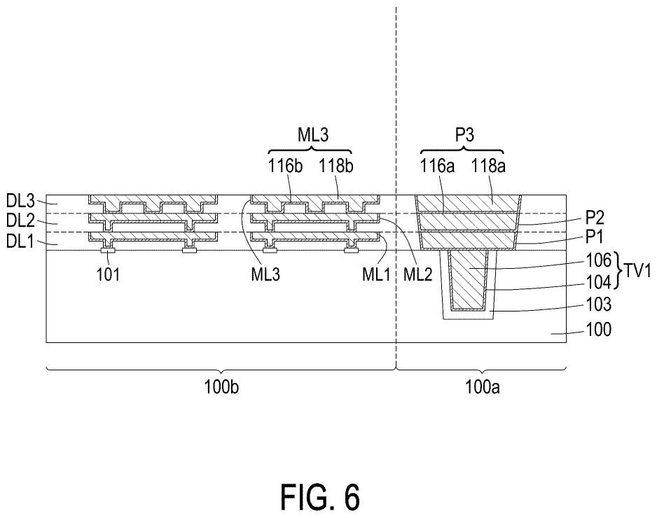

FIG. 6 illustrates forming a third conductive pattern P3 on the second conductive pattern P2 in the first region 100a and simultaneously forming a third conductive layer ML3 on the second conductive layer ML2 in the second region 100b. In some embodiments, the method of forming the third conductive pattern P3 and the third conductive layer ML3 is similar to the method of forming the first conductive pattern P1 and the first conductive layer ML1.

In some embodiments, a dielectric layer DL3 is formed on the dielectric layer DL2 across the first region 100a and the second region 100b. The dielectric layer DL3 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, as shown in the enlarged views of FIG. 17A to FIG. 17D, the dielectric layer DL3 may include two dielectric materials EM3 and two etching stop materials EM3 alternatively stacked. The dielectric layer DL3 is patterned to form a third-level opening in the first region 100a and third-level openings in the second region 100b. The third-level openings are formed simultaneously by the same photolithography and etching processes. The third-level opening in the first region 100a is a hole for defining a part of an upper through via. The third-level opening in the second region 100b is a dual damascene opening including a trench for defining a line and an underlying hole for defining a via. The third-level openings are defined by the same photomask(s). Depending on the process, one or two photomasks may be applied to form the third-level openings.

Thereafter, a metal liner layer 116a and a metal layer 118a are formed in the third-level opening in the first region 100a, and a metal liner layer 116b and a metal layer 118b are formed in the third-level openings in the second region 100b.

In some embodiments, each of the metal liner layers 116a and 116b includes a barrier layer and a seed layer. The barrier layer may include Ta, TaN, Ti, TiN, CoW or a combination thereof. The seed layer may include Cu, Al or the like. For example, each of the metal liner layers 116a and 116b includes Ti and Cu. The metal liner layers 116a and 116b are formed simultaneously by the same sputtering process or deposition process.

In some embodiments, each of the metal layers 118a and 118b may include Cu, Al, Ti, Ta, W, Ru, Co, Ni, the like, or a combination thereof. The metal layers 118a and 118b are formed simultaneously by the same electroplating process or deposition process. For example, the metal layer 118a and 118b are then formed in the third-level openings by using the metal liner layers 116a and 116b as seeds, respectively.

Thereafter, excess materials outside of the third-level openings are removed by a planarization process, such as a chemical mechanical polishing (CMP) process. The remaining metal liner layer 116a and the remaining metal layer 118a constitute a third conductive pattern P3 on the second conductive pattern P2 in the first region 100a in some examples. The remaining metal liner layer 116b and the remaining metal layer 118b constitute a third metal layer ML3 on the second metal layer ML2 in the second region 100b in some examples.

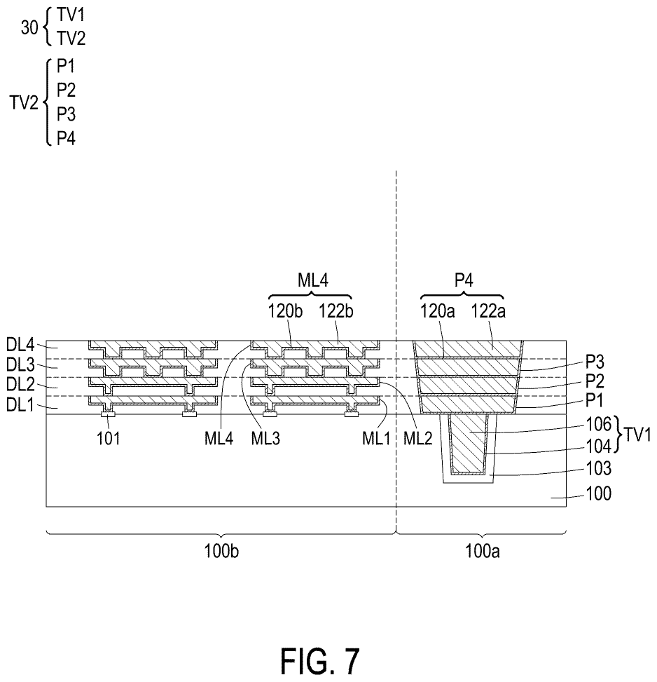

FIG. 7 illustrates forming a fourth conductive pattern P4 on the third conductive pattern P3 in the first region 100a and simultaneously forming a fourth conductive layer ML4 on the third conductive layer ML3 in the second region 100b. In some embodiments, the method of forming the fourth conductive pattern P4 and the fourth conductive layer ML4 is similar to the method of forming the first conductive pattern P1 and the first conductive layer ML1.

In some embodiments, a dielectric layer DL4 is formed on the dielectric layer DL3 across the first region 100a and the second region 100b. The dielectric layer DL4 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, as shown in the enlarged views of FIG. 17A to FIG. 17D, the dielectric layer DL4 may include two dielectric materials DM4 and two etching stop materials EM4 alternatively stacked. The dielectric layer DL4 is patterned to form a fourth-level opening in the first region 100a and fourth-level openings in the second region 100b. The fourth-level openings are formed simultaneously by the same photolithography and etching processes. The fourth-level opening in the first region 100a is a hole for defining a part of an upper through via. The fourth-level opening in the second region 100b is a dual damascene opening including a trench for defining a line and an underlying hole for defining a via. The fourth-level openings are defined by the same photomask(s). Depending on the process, one or two photomasks may be applied to form the fourth-level openings.

Thereafter, a metal liner layer 120a and a metal layer 122a are formed in the fourth-level opening in the first region 100a, and a metal liner layer 120b and a metal layer 122b are formed in the fourth-level opening in the second region 100b.

In some embodiments, each of the metal liner layers 120a and 120b includes a barrier layer and a seed layer. The barrier layer may include Ta, TaN, Ti, TiN, CoW or a combination thereof. The seed layer may include Cu, Al or the like. For example, each of the metal liner layers 120a and 120b includes Ti and Cu. The metal liner layers 120a and 120b are formed simultaneously by the same sputtering process or deposition process.

In some embodiments, each of the metal layers 118a and 118b may include Cu, Al, Ti, Ta, W, Ru, Co, Ni, the like, or a combination thereof. The metal layers 122a and 122b are formed simultaneously by the same electroplating process or deposition process. For example, the metal layer 122a and 122b are then formed in the fourth-level openings by using the metal liner layers 120a and 120b as seeds, respectively.

Thereafter, excess materials outside of the fourth-level openings are removed by a planarization process, such as a chemical mechanical polishing (CMP) process. The remaining metal liner layer 120a and the remaining metal layer 122a constitute a fourth conductive pattern P4 on the third conductive pattern P3 in the first region 100a in some examples. The remaining metal liner layer 120b and the remaining metal layer 122b constitute a fourth metal layer ML4 on the third metal layer ML3 in the second region 100b in some examples.

In some embodiments of the disclosure, the first conductive pattern P1, the second conductive pattern P2, the third conductive pattern P3, and the fourth conductive pattern P4 constitute an upper through via TV2. The upper through via TV2 covers and contacts the lower through via TV1, and the upper through via TV2 and the lower through via TV1 collectively referred to as a through substrate via 30.

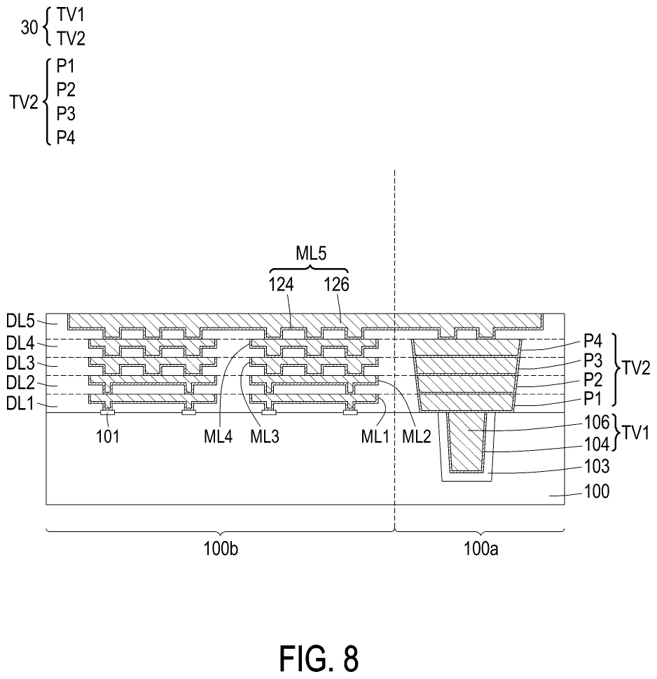

FIG. 8 illustrates forming a fifth conductive layer ML5 electrically connected to the fourth conductive pattern P4 in the first region 100a and the fourth conductive layer ML4 in the second region 100b. In some embodiments, the method of forming the fifth conductive layer ML5 is similar to the method of forming the first conductive layer ML1.

In some embodiments, a dielectric layer DL5 is formed on the dielectric layer DL4 across the first region 100a and the second region 100b. The dielectric layer DL5 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, as shown in the enlarged views of FIG. 17A to FIG. 17D, the dielectric layer DL5 may include two dielectric materials DM5 and two etching stop materials EM5 alternatively stacked. The dielectric layer DL5 is patterned to form fifth-level openings in the first region 100a and the second region 100b. The fifth-level openings are formed by photolithography and etching processes. Each of the fifth-level openings in the first region 100a and the second region 100b is a dual damascene opening including a trench for defining a line and an underlying hole for defining a via. The fifth-level openings are defined by the same photomask(s). Depending on the process, one or two photomasks may be applied to form the fifth-level openings.

Thereafter, a metal liner layer 124 and a metal layer 126 are formed in the fifth-level openings in the first region 100a and the second region 100b.

In some embodiments, the metal liner layer 304 includes a barrier layer and a seed layer. The barrier layer may include Ta, TaN, Ti, TiN, CoW or a combination thereof. The seed layer may include Cu, Al or the like. For example, the metal liner layer 304 includes Ti and Cu. The metal liner layer 304 is formed by a sputtering process or a deposition process.

The metal layer 126 may include Cu, Al, Ti, Ta, W, Ru, Co, Ni, the like, or a combination thereof. The metal layer 126 is formed by an electroplating process or a deposition process. For example, the metal layer 126 is then formed in the fifth-level openings by using the metal liner layer 124 as a seed.

Thereafter, excess materials outside of the fifth-level openings are removed by a planarization process, such as a chemical mechanical polishing (CMP) process. The remaining metal liner layer 124 and the remaining metal layer 126 constitute a fifth metal layer ML5 on the fourth conductive pattern P4 in the first region 100a and on the fourth metal layer ML4 in the second region 100b in some examples.

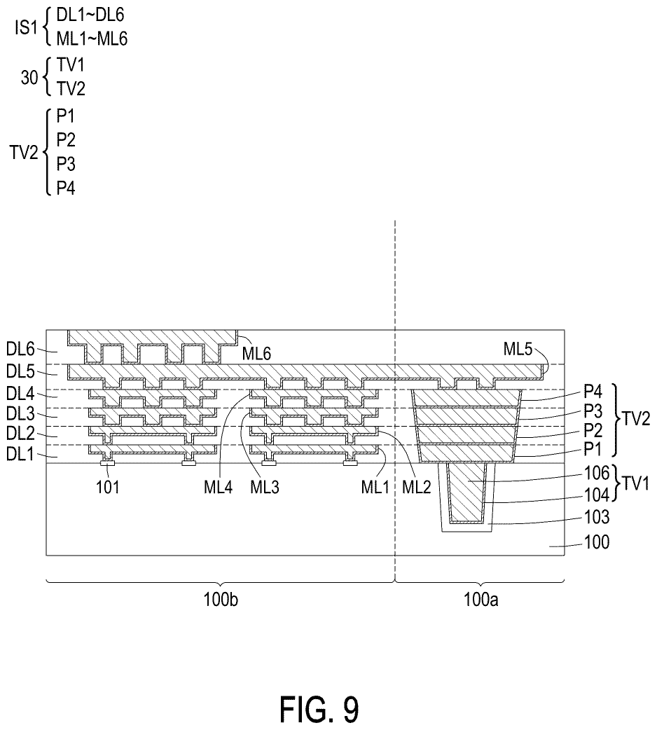

FIG. 9 illustrates forming a sixth conductive layer ML6 electrically connected to the fifth conductive layer ML5. In some embodiments, the method of forming the sixth conductive layer ML6 is similar to the method of forming the first conductive layer ML1.

In some embodiments, a dielectric layer DL6 is formed on the dielectric layer DL5 across the first region 100a and the second region 100b. The dielectric layer DL6 includes at least one etching stop material and at least one dielectric material having different materials and etching selectivities. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, the dielectric layer DL6 may include two dielectric materials and two etching stop materials alternatively stacked. The dielectric layer DL6 is patterned to form sixth-level openings in the second region 100b. The sixth-level openings are formed by photolithography and etching processes. Each of the sixth-level openings is a dual damascene opening including a trench for defining a line and an underlying hole for defining a via. The sixth-level openings are defined by the same photomask(s). Depending on the process, one or two photomasks may be applied to form the sixth-level openings.

Thereafter, a metal liner layer and a metal layer are formed in the sixth-level openings. The materials and forming methods of the metal liner layer and the metal layer are similar to those of the metal liner layer 124 and the metal layer 126, so the details are not iterated herein. The metal liner layer 124 and the metal layer 126 constitute a sixth metal layer ML6 on the fifth metal layer ML5. In some embodiments, the sixth metal layer ML6 is formed in the second region 100b, but the disclosure is not limited thereto. In other embodiments, the sixth metal layer ML6 is formed across the first region 100a and the second region 100b.

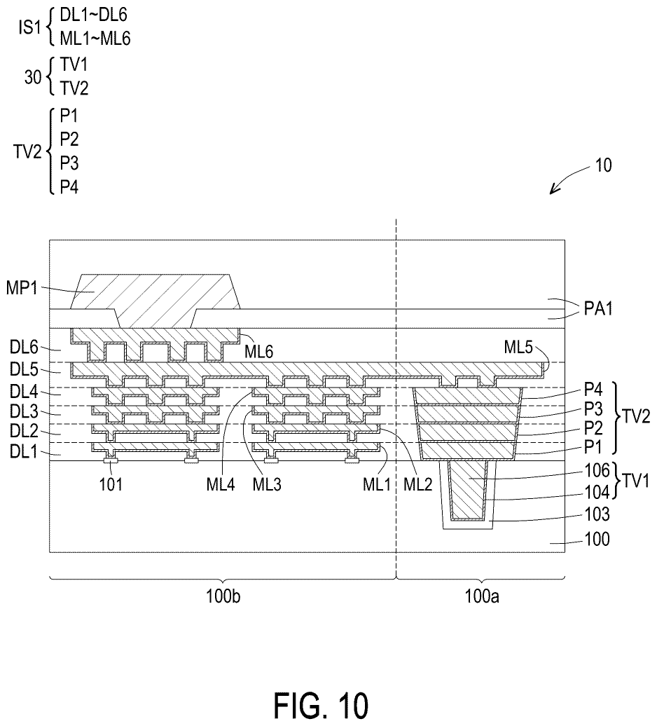

FIG. 10 illustrates forming at least one metal pad MP1 electrically connected to the sixth conductive layer ML6. In some embodiments, the metal pad MP1 is embedded in passivation layers PA1. In some embodiments, the metal pad MP1 is an aluminum pad. The aluminum pad is a test pad, and may have a probe mark thereon. In other embodiments, the metal pad MP1 is a copper pad. The passivation layers PA1 may include a polymer material such as polybenzoxazole (PBO), polyimide (PI), benzocyclobutene (BCB), the like, or a combination thereof. A first die 10 of the disclosure is thus completed. The lower through via TV1 is not exposed at the current stage.

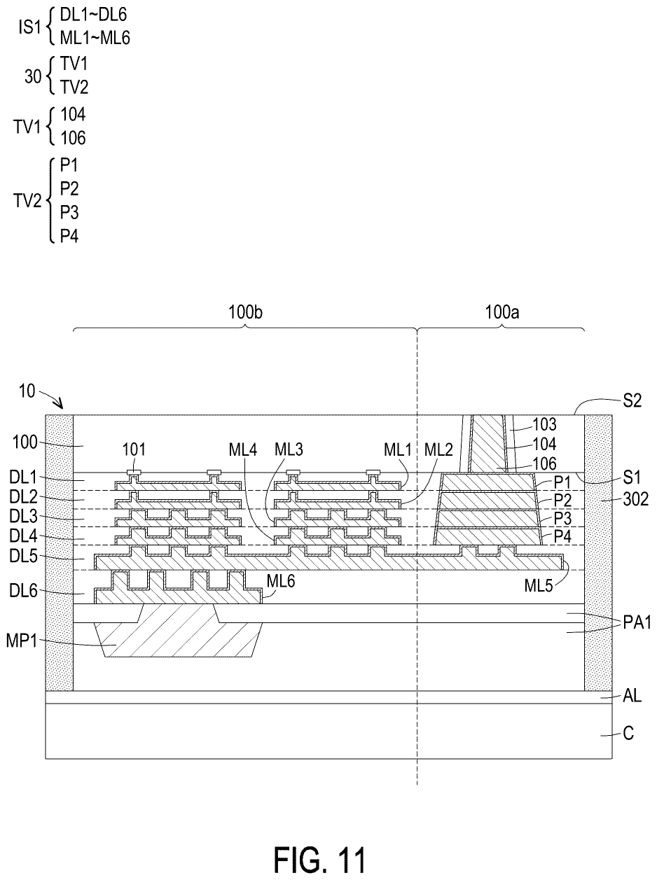

FIG. 11 illustrates thinning the substrate 100 until the surface of the lower through via TV1 is exposed. In some embodiments, the first die 10 of FIG. 10 is flipped over, and a carrier C is attached to the passivation layer PA1 with an adhesion layer AL therebetween. The carrier C is a sacrificial carrier and will be removed later. The carrier C may include a silicon carrier or a glass carrier. The adhesive layer AL may include a Ultra-Violet (UV) glue, a Light-to-Heat Conversion (LTHC) glue, or the like, although other types of adhesives may be used.

Thereafter, a dielectric layer 302 is formed to encapsulate and cover the first die 10. The dielectric layer 304 may include silicon oxide or the like. Afterwards, a thinning process is performed to the substrate 100 from the second side S2, so as to reduce the thickness of the substrate 100. For example, the thinned substrate 100 ranges from about 10 μm to 20 μm. The thinning process includes a grinding process or a polishing process. The thinning process removes a portion of the substrate 100, a portion of the insulating liner layer 103 and a portion of the metal liner layer 104, so the surface of the remaining metal layer 106 of the lower through via TV1 is coplanar with the second side S2 of the substrate 100. The thinning process also removes a portion of the dielectric layer 302, so the remaining dielectric layer 302 is coplanar with the backside surface of the substrate 100.

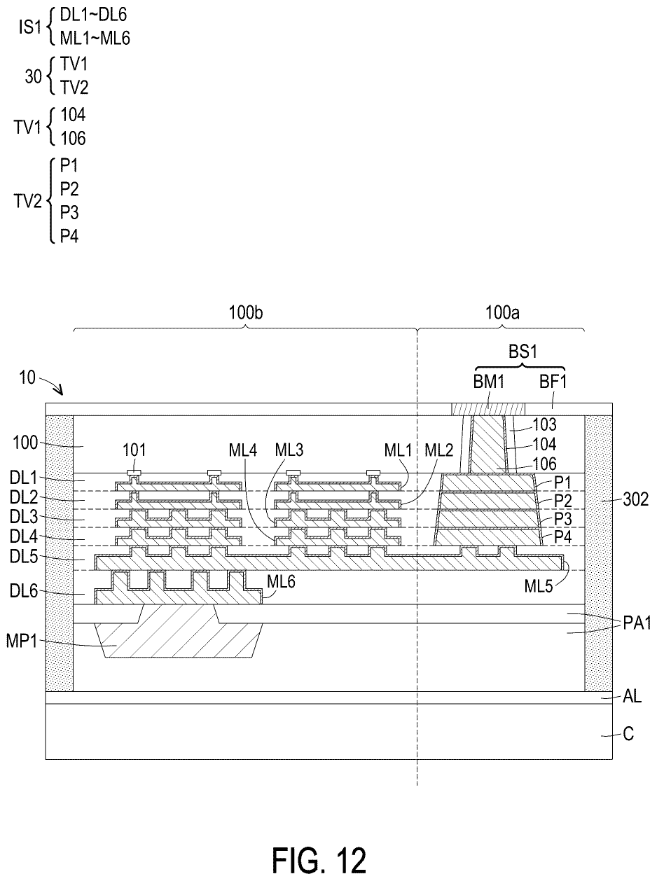

FIG. 12 illustrates forming a bonding structure BSl on the lower through via TV1. In some embodiments, the bonding structure BSl includes one or more bonding metal features BM1 embedded in a bonding dielectric layer BF1. The bonding metal feature BM1 includes a bonding pad. The bonding metal feature BM1 includes Cu, Al, Co, Cr, W, Ti, Ta, TiN, TaN, the like or a combination thereof. The bonding dielectric layer BF1 includes silicon oxide, silicon nitride or silicon oxynitirde. In some embodiments, the bonding structure BSl is regarded as part of the first die 10 of the disclosure. In some embodiments, the bonding structure BSl extends beyond the sidewall of the first die 10, as shown in FIG. 12. However, the disclosure is not limited thereto. In other embodiments, the sidewall of the bonding structure BSl is substantially flush with the sidewall of the first die 10.

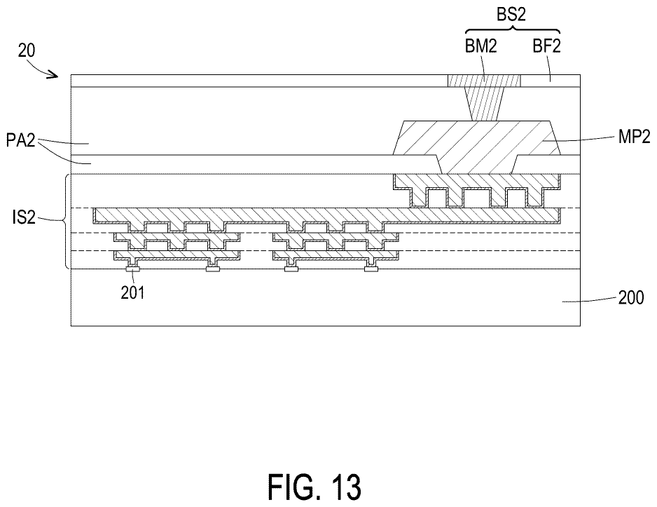

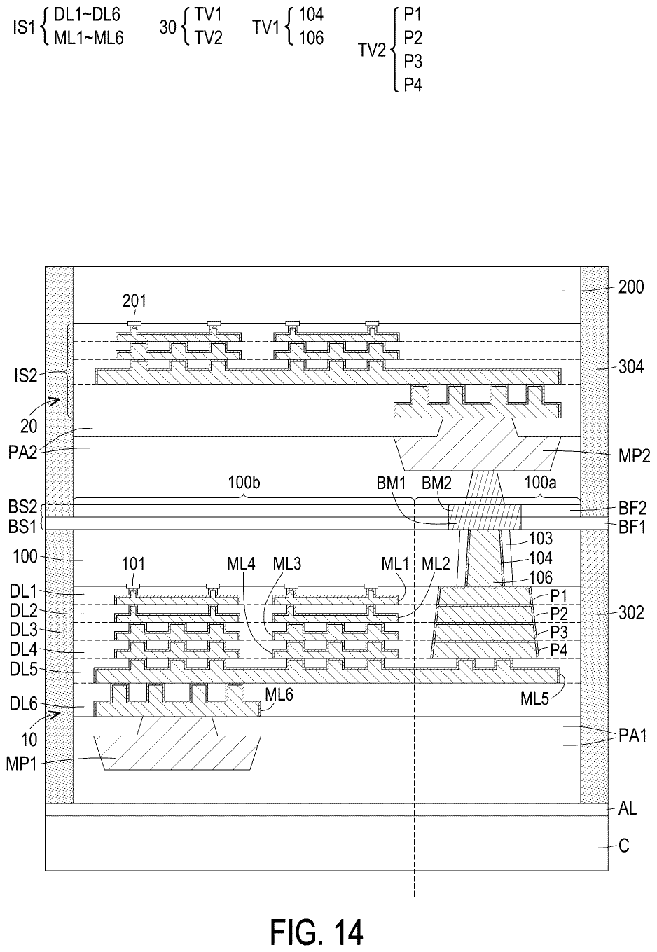

FIG. 13 and FIG. 14 illustrate providing a second die 20 and bonding the second die 20 to the first die 10. In some embodiments, the second die 20 may include a substrate 200, devices 201 at an active side (e.g., front side) of the substrate 200, an interconnect structure IS2 on the active side of the substrate 200, a metal pad MP2 on the interconnect structure IS2, and a bonding structure BS2 on the metal pad MP2.

In some embodiments, the substrate 200 may be a semiconductor substrate such as a silicon substrate. In other embodiments, the substrate 200 includes an elementary semiconductor such as germanium; a compound semiconductor including silicon carbon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates such as multi-layered or gradient substrates may also be used. The substrate 200 is hundreds of micron-scale.

In some embodiments, the devices 201 may include active and/or passive devices. For example, the devices 201 may include transistors, diodes, capacitors, resistors, or the like, formed by any suitable formation method.

In some embodiments, the interconnect structure IS2 includes metal features embedded in dielectric layers. The metal features include metal lines and metal vias electrically connected to each other. Each metal feature includes a metal liner material and a metal material. In some embodiments, the metal liner material includes a barrier layer and a seed layer. The barrier layer may include Ta, TaN, Ti, TiN, CoW or a combination thereof. The seed layer may include Cu, Al or the like. For example, the metal liner material includes Ti and Cu. In some embodiments, the metal material may include Cu, Al, Ti, Ta, W, Ru, Co, Ni, the like, or a combination thereof. The dielectric layers include dielectric materials and etching stop materials between adjacent dielectric materials. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5.

In some embodiments, the metal pad MP2 is embedded in passivation layers PA2. In some embodiments, the metal pad MP2 is an aluminum pad. The aluminum pad is a test pad, and may have a probe mark thereon. In other embodiments, the metal pad MP2 is a copper pad. The passivation layers PA2 may include a polymer material such as polybenzoxazole (PBO), polyimide (PI), benzocyclobutene (BCB), the like, or a combination thereof.

In some embodiments, the bonding structure BS2 includes one or more bonding metal features BM2 embedded in a bonding dielectric layer BF2. The bonding metal feature BM2 includes a bonding pad, a bonding via or a combination thereof. The bonding metal feature BM2 includes Cu, Al, Co, Cr, W, Ti, Ta, TiN, TaN, the like or a combination thereof. The bonding dielectric layer BF2 includes silicon oxide, silicon nitride or silicon oxynitirde. In some embodiments, the bonding structure BS2 is regarded as part of the first die 20 of the disclosure. In some embodiments, the sidewall of the bonding structure BS2 is substantially flush with the sidewall of the first die 20. However, the disclosure is not limited thereto. In other embodiments, the bonding structure BS2 extends beyond the sidewall of the second die 20.

Referring to FIG. 14, the second die 20 is bonded to the first die 10 through a mixed bonding including a metal-to-metal bonding and a dielectric-to-dielectric bonding. For example, the bonding metal feature BM2 is bonded to the bonding metal feature BM1, and the bonding dielectric layer BF2 is bonded to the bonding dielectric layer BF1. In some embodiments, the width of the bonding metal feature BM2 is substantially the same with the width of the bonding metal feature BM1, but the disclosure is not limited thereto. In other embodiments, the width of the bonding metal feature BM2 is different from (e.g., greater than or smaller than) the width of the bonding metal feature BM1. In some embodiments, the material of the bonding dielectric layer BF2 (e.g., silicon oxynitride) is different from the material of the bonding dielectric layer BF1 (e.g., silicon oxide), but the disclosure is not limited thereto. In other embodiments, the material of the bonding dielectric layer BF2 is the same as the material of the bonding dielectric layer BF1.

Thereafter, a dielectric layer 304 is formed to encapsulate and cover the second die 20. The dielectric layer 304 may include silicon oxide or the like. In some embodiments, a thinning process is performed to the substrate 200 of the second die 20, so as to reduce the thickness of the substrate 200. For example, the thinned substrate 200 ranges from about 10 μm to 20 μm. The thinning process also removes a portion of the dielectric layer 304, so the remaining dielectric layer 304 is coplanar with the backside surface of the substrate 200.

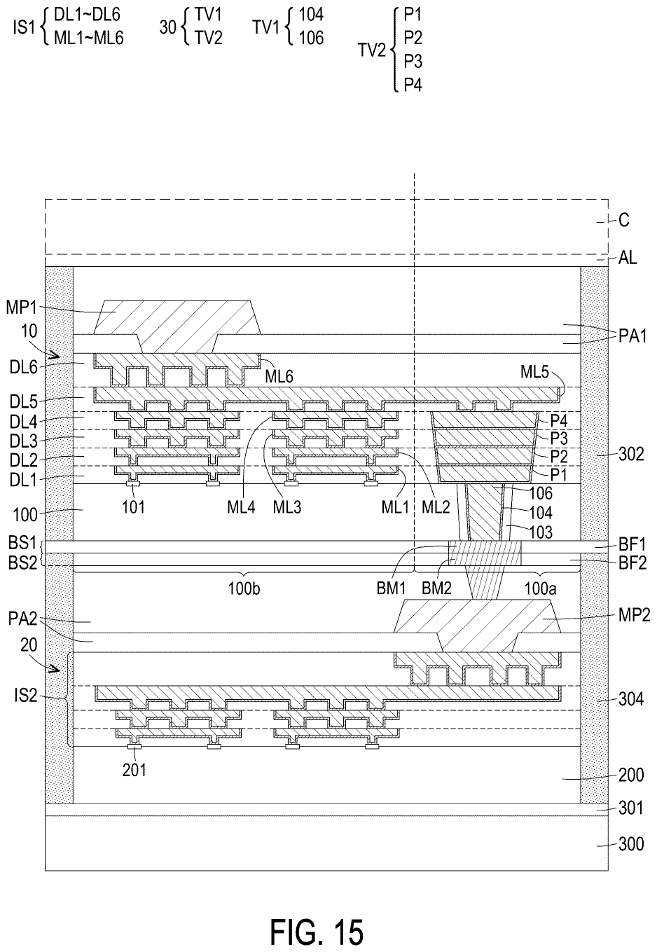

FIG. 15 illustrates attaching a support substrate 300 to the second die 20. In some embodiments, the support substrate 300 includes a silicon support or a suitable support. In some embodiments, the support substrate 300 has a thickness of about 500 μm to about 1000 μm, such as about 600 μm to about 800 μm. The thick support substrate 300 of the disclosure is beneficial for heat dissipation and package stiffness. The support substrate 300 is referred to as a “heat dissipation carrier” in some examples.

In some embodiments, the support substrate 300 is attached to the second die 20 through a buffer layer 301. In some embodiments, the buffer layer 301 may include a dielectric material, such as SiO₂, SiN, SiON, SiC, SiCN, SiCO or a combination thereof. In some embodiments, the buffer layer 301 may be made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat spreader material may include AlN, GaN, ZnO, BN, Al₂O₃, HfO₂, TiO₂ or a combination thereof. In some embodiments, the buffer layer 301 has a thickness of about 0.01 μm to about 2.5 μm. The buffer layer 301 of the disclosure may have a single-layer or multi-layer structure.

Thereafter, the structure of FIG. 15 is turned over and the carrier C is removed from the first die 10. In some embodiments, the adhesive layer AL is further removed to expose the passivation layer PA1 of the first die 10. In some embodiments, the removing process includes an etching process or a suitable process.

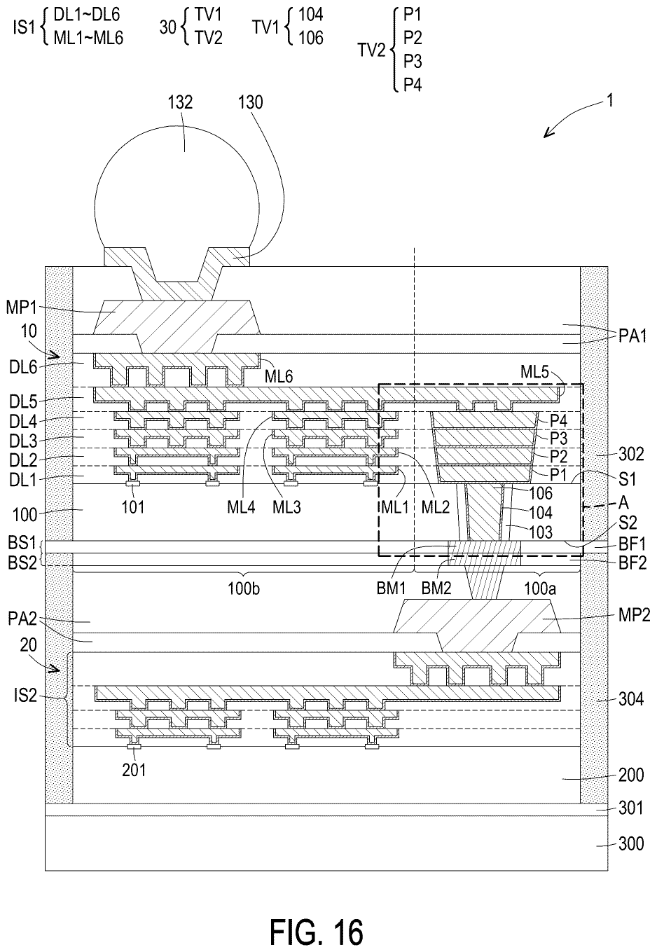

FIG. 16 illustrates forming a bump 132 electrically connected to the first die 10. In some embodiments, an under-bump metallization (UBM) pad 130 is formed through the passivation layer PA1 and landed on the metal pad MP1. In some embodiments, the UBM pad 130 is part of a redistribution layer structure (RDL) disposed between the bump 132 and the metal pad MP2. The redistribution layer structure may include metal features embedded by dielectric layers and electrically connected to each other. The metal features include metal lines and metal vias electrically connected to each other. Each metal feature includes a metal liner material and a metal material. In some embodiments, the metal liner material includes a barrier layer and a seed layer. The barrier layer may include Ta, TaN, Ti, TiN, CoW or a combination thereof. The seed layer may include Cu, Al or the like. For example, the metal liner material includes Ti and Cu. In some embodiments, the metal material may include Cu, Al, Ti, Ta, W, Ru, Co, Ni, the like, or a combination thereof. The dielectric layers include dielectric materials and etching stop materials between adjacent dielectric materials. The etching stop material may include aluminum nitride, aluminum oxide, aluminum oxynitride, silicon nitride, silicon carbide or a combination thereof. The dielectric material may include silicon oxide, silicon oxynitride, silicon oxycarbide or a low-k material having a dielectric constant less than 3.5 or 2.5. In some embodiments, the redistribution layer structure is regarded as part of the first die 10. In some embodiments, the critical dimension of the redistribution layer structure is greater than the critical dimension of the interconnection structure IS1.

Thereafter, a conductive terminal or a bump 132 is formed over and electrically connected to the UBM pad 130 of the redistribution layer structure. In some embodiments, the bump 132 may be a solder bump, and/or may include a metal pillar (e.g., copper pillar), solder cap formed on metal pillar, and/or the like. The bump 132 may be formed by a suitable process such as evaporation, electroplating, ball drop, or screen printing. A semiconductor structure 1 of some embodiments is thus completed.

The related through substrate via of the related semiconductor structure is formed by defining a single deep opening with a dry etching and a wet strip, followed by a single electroplating process. The related guard ring is required for the related through substrate via to protect against the moisture effect caused by the long-time wet strip process during the deep opening defining step. However, the through substrate via of the disclosure is free of a surrounding guard ring, because the through substrate via of the disclosure is formed by multiple conductive patterns stacked on one another, rather than a single conductive via. The wet strip process is short and the moisture effect is relatively minor, and thus, the related guard ring is not necessary. Since the through substrate via of the disclosure is a non-guard ring TSV structure, so the keep out zone is relatively smaller.

FIG. 17A illustrates top and cross-sectional views of a local region A of the semiconductor structure in FIG. 16 in accordance with some embodiments of the present disclosure. FIG. 17B to FIG. 17D illustrate different cross-sectional views of part of the semiconductor structure in FIG. 16 in accordance with other embodiments of the present disclosure.

As shown in FIG. 17A, the keep out zone D1 from the sidewall of the lower through via TV1 to the sidewall of the interconnect structure IS1 is less than about 1.5 μm. In some embodiments, the through substrate via 30 has a step profile at the silicon substrate interface. For example, the distance D2 from the sidewall of the lower through via TV1 to the sidewall of the upper through via TV2 is greater than zero, e.g., about 0.1 μm or more, or about 0.5 μm or more. In some embodiments, the barrier thickness D3 of the upper through via TV2 is greater than zero, e.g., about 0.02 μm or more. In some embodiments, the barrier thickness D3 of the upper through via TV2 is 0.5 μm or less. In some embodiments, the aspect ratio of D4/D5 is less than about 12, less than about 5 or less than about 1. In some embodiments, when multiple through substrate vias 30 are included in the first die 10, the pitch D6 of the through substrate vias 30 is about 3 μm or less.

In some embodiments, the upper through via TV2 has a smooth sidewall, in which the sidewalls of the adjacent conductive patterns are substantially flush with each other, as shown in FIG. 17A. However, the disclosure is not limited thereto. In other embodiments, the upper through via TV2 may have a stepped or non-smooth sidewall, in which the sidewalls of the adjacent conductive patterns are not flush with each other, as shown in FIG. 17B and FIG. 17C. Specifically, at least one of the conductive patterns of the upper through via TV2 may be protruded from or recessed from the adjacent conductive pattern, so the sidewall of the upper through via TV2 has one or more turning points.

In some embodiments, the central axis of the lowermost conductive pattern P1 of the upper through via TV2 is substantially aligned with the central axis of the lower through via TV1, as shown in FIG. 17A. However, the disclosure is not limited thereto. In other embodiments, the central axis of the lowermost conductive pattern P1 of the upper through via TV2 is offset with (e.g., shifted from) the central axis of the lower through via TV1, so the distances D2 from opposite sidewalls of the lower through via TV1 to the correspond sidewalls of the upper through via TV2 are different from each other, as shown in FIG. 17C.

In some embodiments, each of the conductive patterns of the upper through via TV1 has a substantially straight sidewall, as shown in FIG. 17A to FIG. 17C. However, the disclosure is not limited thereto. In other embodiments, each of the conductive patterns of the upper through via TV2 has a stepped sidewall, as shown in FIG. 17D. In some embodiments, each of the conductive patterns of the upper through via TV2 has a dual damascene structure or a T-shaped structure.

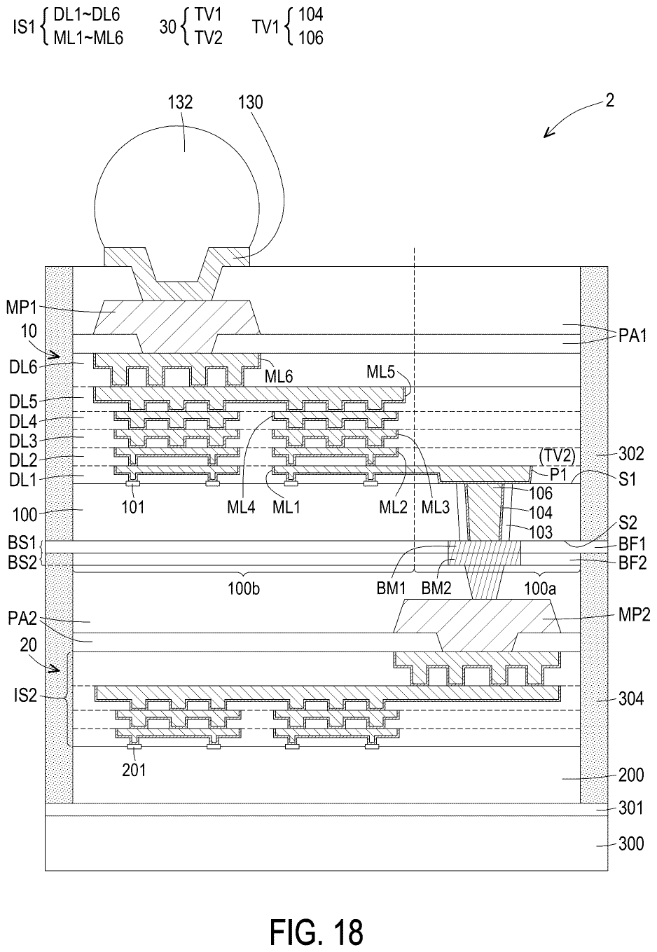

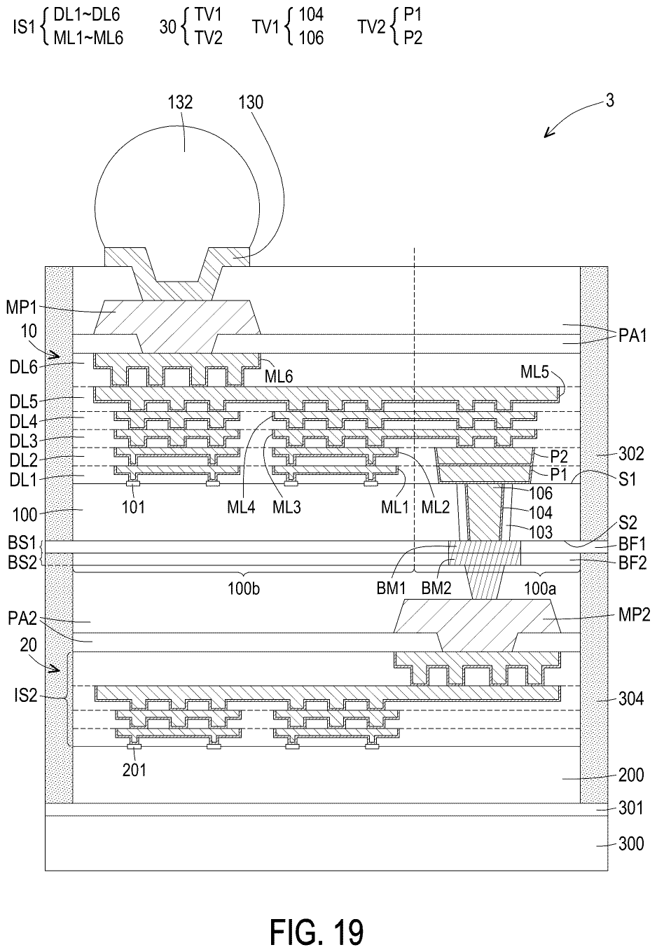

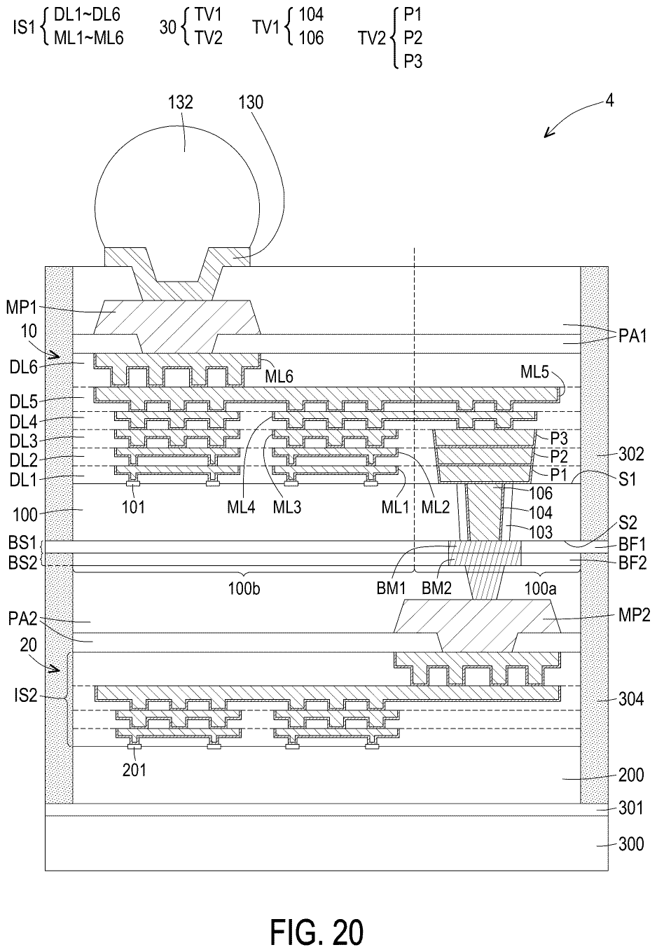

As shown in FIG. 16, N (wherein N=4) conductive patterns of the upper through via TV2 are formed simultaneously with N (wherein N=4) conductive layers of the interconnect structure IS1, and the Nth conductive pattern (e.g., P4) and the Nth conductive layer (e.g., ML4) are electrically connected to each other through the (N+1)-th conductive layer (e.g., ML5) of the interconnect structure. However, the number N of the conductive patterns or the conductive layers is not limited by the disclosure. The number N of the conductive patterns or the conductive layers can be less than 4 or greater than 4 upon the process requirements. FIG. 18 to FIG. 20 respectively illustrate the scenarios of N=1, N=2, and N=3, as shown in semiconductor structures 2, 3 and 4. Besides, different sidewall profiles (e.g., smooth or stepped sidewalls) illustrated in FIG. 17A to FIG. 17D are applicable to the upper through vias TV2 of the semiconductor structures 2, 3 and 4.

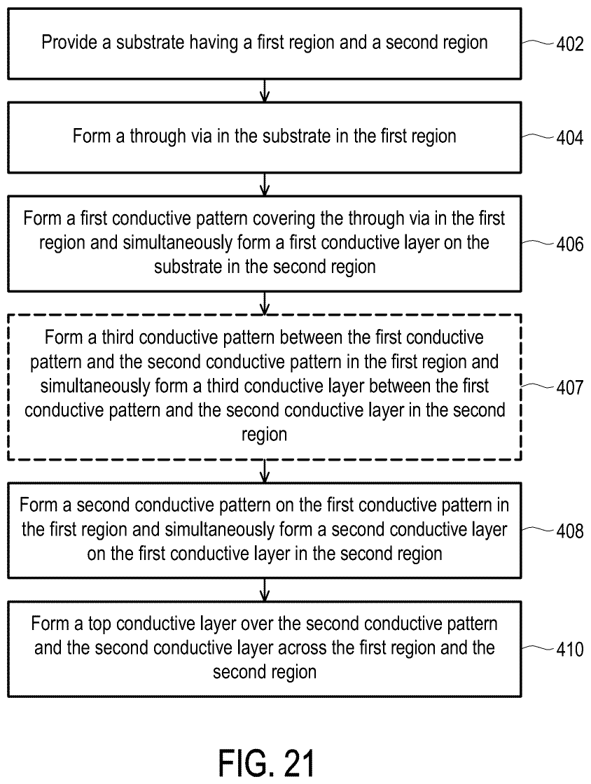

FIG. 21 illustrates a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 402, a substrate having a first region and a second region is provided. FIG. 1 illustrates a cross-sectional view corresponding to some embodiments of act 402.

At act 404, a through via is formed in the substrate in the first region. FIG. 1 and FIG. 2 illustrate cross-sectional views corresponding to some embodiments of act 404.

At act 406, a first conductive pattern is formed covering the through via in the first region and a first conductive layer is simultaneously formed on the substrate in the second region. FIG. 3 and FIG. 4 illustrate cross-sectional views corresponding to some embodiments of act 406. In some embodiments, a width of the first conductive pattern is greater than a width of the through via.

At act 408, a second conductive pattern is formed on the first conductive pattern in the first region and a second conductive layer is simultaneously formed on the first conductive layer in the second region. Accordingly, at least two conductive patterns are stacked on the through via in the first region. FIG. 5 to FIG. 7 illustrate cross-sectional views corresponding to some embodiments of act 408. In some embodiments, a sidewall of the second conductive pattern is aligned with a sidewall of the first conductive pattern. In other embodiments, a sidewall of the second conductive pattern is offset with a sidewall of the first conductive pattern.

In some embodiments, a third conductive pattern is optionally formed between the first conductive pattern and the second conductive pattern in the first region, and a third conductive layer is further formed and simultaneously formed between the first conductive pattern and the second conductive layer in the second region (act 407). Accordingly, at least three conductive patterns are stacked on the through via in the first region, as shown in FIG. 6 to FIG. 7. In some embodiments, a sidewall of the third conductive pattern is aligned with a sidewall of the first conductive pattern or the second conductive pattern. In other embodiments, a sidewall of the third conductive pattern is offset with a sidewall of the first conductive pattern or the second conductive pattern.

At act 410, a top conductive layer is formed over the second conductive pattern and the second conductive layer across the first region and the second region. FIG. 8 illustrates a cross-sectional view corresponding to some embodiments of act 410.

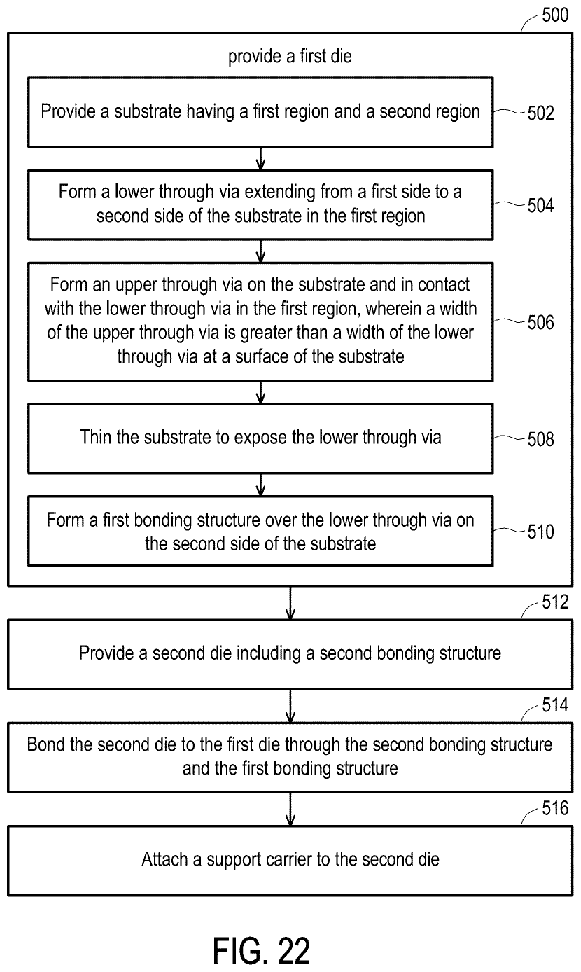

FIG. 22 illustrates a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 500, a first die is provided. In some embodiments, act 500 includes act 502 to act 510.

At act 502, a substrate having a first region and a second region is provided. FIG. 1 illustrates a cross-sectional view corresponding to some embodiments of act 502.

At act 504, a lower through via is formed extending from a first side to a second side of the substrate in the first region. FIG. 1 and FIG. 2 illustrate cross-sectional views corresponding to some embodiments of act 504.

At act 506, an upper through via is formed on the substrate and in contact with the lower through via in the first region, wherein a width of the upper through via is greater than a width of the lower through via at a surface of the substrate. FIG. 3 to FIG. 10 illustrate cross-sectional views corresponding to some embodiments of act 506. In some embodiments, forming the upper through via includes forming a plurality conductive patterns stacked on one another. In some embodiments, an interconnect structure is further formed and simultaneously formed on the substrate in the second region during forming the upper through via in the first region. In some embodiments, the upper through via and the interconnect structure are defined by the same photomasks.

At act 508, the substrate is thinned to expose the lower through via. FIG. 11 illustrates a cross-sectional view corresponding to some embodiments of act 508.

At act 510, a first bonding structure is formed over the lower through via on the second side of the substrate. FIG. 12 illustrates a cross-sectional view corresponding to some embodiments of act 510.

At act 512, a second die including a second bonding structure is provided. FIG. 13 illustrates a cross-sectional view corresponding to some embodiments of act 512.

At act 514, the second die is bonded to the first die through the second bonding structure and the first bonding structure. FIG. 14 illustrates a cross-sectional view corresponding to some embodiments of act 514.

At act 516, a support carrier is attached to the second die. FIG. 15 to FIG. 16 illustrate cross-sectional views corresponding to some embodiments of act 516.

The semiconductor structures of the disclosure are illustrated below with reference to FIG. 16 to FIG. 20. In some embodiments, a semiconductor structure 1/2/3/4 includes a substrate 100, a through via TV1 and a first conductive pattern P1. The substrate 100 has a first region 100a and a second region 100b. The through via TV1 is disposed in the substrate 100 in the first region 100a. The first conductive pattern P1 is disposed on the substrate 100 and landed on (e.g., in contact with) the through via TV1 in the first region 100a. In some embodiments, a width of the first conductive pattern P1 is greater than a width of the through via TV1.

In some embodiments, the semiconductor structure 1/2/3/4 further includes a first conductive layer ML1 disposed on the substrate 100 in the second region 100b, and a top surface of the first conductive pattern P1 is coplanar with a top surface of the first conductive layer ML1. Specifically, the first conductive pattern P1 and the first conductive layer ML1 are disposed at substantially the same level.

In some embodiments, the semiconductor structure 1/3/4 further includes a second conductive pattern P2 landed on the first conductive pattern P1 in the first region 100a, and a second conductive layer ML2 disposed on the first conductive layer ML1 in the second region 100b, wherein a top surface of the second conductive pattern P2 is coplanar with a top surface of the second conductive layer ML2. Specifically, the second conductive pattern P2 and the second conductive layer ML2 are disposed at substantially the same level.

In some embodiments, a sidewall of the first conductive pattern P1 is flush with a sidewall of the second conductive pattern P2. In other embodiments, a sidewall of the first conductive pattern P1 is offset with a sidewall of the second conductive pattern P2.

In some embodiments, the semiconductor structure ¼ further includes a third conductive pattern P3 landed on the second conductive pattern P2 in the first region 100a, and a third conductive layer ML3 disposed on the second conductive layer ML2 in the second region 100b, wherein a top surface of the third conductive pattern P3 is coplanar with a top surface of the third conductive layer ML3. Specifically, the third conductive pattern P3 and the third conductive layer ML3 are disposed at substantially the same level.

In some embodiments, a sidewall of the third conductive pattern P3 is flush with a sidewall of the second conductive pattern P2. In other embodiments, a sidewall of the third conductive pattern P3 is offset with a sidewall of the second conductive pattern P2.

In view of the above, the through substrate via of the disclosure is defined by forming multiple shallow openings and performing multiple electroplating processes alternately. The wet strip process is short and the moisture effect is relatively minor, and thus, the related guard ring is not necessary. Accordingly, the through substrate via of the disclosure increases the keep out zone and gains the design flexibility. Besides, in the disclosure, the shallow conductive patterns of the through substrate via and the adjacent conductive layers of the interconnect structure can be defined simultaneously with the same photomasks. The method of the disclosure is compatible with the existing processes without increasing process steps and costs.

According to an aspect of the present disclosure, a method of forming a semiconductor structure is provided. A substrate is provided with a first region and a second region. A through via is formed in the substrate in the first region. A first conductive pattern is formed covering the through via in the first region and a first conductive layer is simultaneously formed on the substrate in the second region. A second conductive pattern is formed on the first conductive pattern in the first region and a second conductive layer is simultaneously formed on the first conductive layer in the second region.

According to an aspect of the present disclosure, a method of forming a semiconductor structure is provided. A first die is provided and formed by the following operations. A substrate is provided with a first region and a second region. A lower through via is formed extending from a first side to a second side of the substrate in the first region. An upper through via is formed on the substrate and in contact with the lower through via in the first region, wherein a width of the upper through via is greater than a width of the lower through via at a surface of the substrate. The substrate is thinned to expose the lower through via.

According to an aspect of the present disclosure, a semiconductor structure includes a substrate, a through via and a first conductive pattern. The substrate has a first region and a second region. The through via is disposed in the substrate in the first region. The first conductive pattern is disposed on the substrate and landed on the through via in the first region, wherein a width of the first conductive pattern is greater than a width of the through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
providing a substrate having a first region and a second region;
forming a through via in the substrate in the first region;
forming a first conductive pattern covering the through via in the first region and forming a first conductive layer on the substrate in the second region; and
forming a second conductive pattern on the first conductive pattern in the first region and forming a second conductive layer on the first conductive layer in the second region.

2. The method of claim 1, wherein a width of the first conductive pattern is greater than a width of the through via.

3. The method of claim 1, wherein a sidewall of the second conductive pattern is aligned with a sidewall of the first conductive pattern.

4. The method of claim 1, wherein a sidewall of the second conductive pattern is offset with a sidewall of the first conductive pattern.

5. The method of claim 1, further comprising forming a third conductive pattern between the first conductive pattern and the second conductive pattern in the first region and forming a third conductive layer between the first conductive layer and the second conductive layer in the second region.

6. The method of claim 5, wherein a sidewall of the third conductive pattern is aligned with a sidewall of the first conductive pattern or the second conductive pattern.

7. The method of claim 5, wherein a sidewall of the third conductive pattern is offset with a sidewall of the first conductive pattern or the second conductive pattern.

8. The method of claim 1, further comprising forming a top conductive layer over the second conductive pattern and the second conductive layer across the first region and the second region.

9. A method of forming a semiconductor structure, comprising:
providing a first die, wherein a method of forming the first die comprises:
providing a substrate having a first region and a second region;
forming a lower through via extending from a first side to a second side of the substrate in the first region;
forming an upper through via on the substrate and in contact with the lower through via in the first region, wherein a width of the upper through via is greater than a width of the lower through via at a surface of the substrate; and
thinning the substrate to expose the lower through via.

10. The method of claim 9, wherein forming the upper through via comprises forming a plurality conductive patterns stacked on one another.

11. The method of claim 9, further comprising forming an interconnect structure on the substrate in the second region during forming the upper through via in the first region.

12. The method of claim 11, wherein the upper through via and the interconnect structure are defined by the same photomasks.

13. The method of claim 9, further comprising forming a first bonding structure over the lower through via on the second side of the substrate.

14. The method of claim 13, further comprising:
providing a second die comprising a second bonding structure; and
bonding the second die to the first die through the second bonding structure and the first bonding structure.

15. The method of claim 14, further comprising attaching a support carrier to the second die.

16. A semiconductor structure, comprising:
a substrate having a first region and a second region;
a through via disposed in the substrate in the first region; and
a first conductive pattern disposed on the substrate and on the through via in the first region, wherein a width of the first conductive pattern is greater than a width of the through via.

17. The semiconductor structure of claim 16, further comprising a first conductive layer disposed on the substrate in the second region, wherein a top surface of the first conductive pattern is substantially coplanar with a top surface of the first conductive layer.

18. The semiconductor structure of claim 17, further comprising:
a second conductive pattern landed on the first conductive pattern in the first region; and
a second conductive layer disposed on the first conductive layer in the second region,
wherein a top surface of the second conductive pattern is coplanar with a top surface of the second conductive layer.

19. The semiconductor structure of claim 18, wherein a sidewall of the first conductive pattern is flush with a sidewall of the second conductive pattern.

20. The semiconductor structure of claim 18, wherein a sidewall of the first conductive pattern is offset with a sidewall of the second conductive pattern.
